(19) United States
(12) Patent Application Publication
(10) Pub. No.: US 2026/0148767 A1
(43) Pub. Date: May 28, 2026

(54) METHOD FOR WRITING TO MEMORY AND MEMORY DEVICE SUPPORTING THE SAME

(71) Applicant: Samsung Electronics Co., Ltd., Suwon-si (KR)

(72) Inventors: Seulji SONG, Suwon-si (KR); Suhyun BANG, Suwon-si (KR); Jongmin BAEK, Suwon-si (KR)

(21) Appl. No.: 19/247,274

(22) Filed: Jun. 24, 2025

(30) Foreign Application Priority Data
Nov. 26, 2024 (KR) 10-2024-0171352

(51) Int. Cl. G11C 13/00

(52) U.S. Cl. CPC G11C 13/0069; G11C 13/0026; G11C 13/0028; G11C 13/0038

(57) ABSTRACT

A method of writing to a memory includes selecting a polarity for writing based on a type of write data, applying a first reference voltage to a first line selected from a word line and a bit line according to an operation of a global decoder pair corresponding to the polarity, in response to the first line reaching the first reference voltage, floating the first line, and applying a second reference voltage to a second line which is different from the first line among the word line and the bit line according to the operation of the global decoder pair.

### CROSS-REFERENCE TO RELATED APPLICATION(S)

This application claims the benefit to Korean Patent Application No. 10-2024-0171352, filed in the Korean Intellectual Property Office on Nov. 26, 2024, the disclosure of which is incorporated herein by reference in its entirety.

### BACKGROUND

A memory device stores information by reading and writing data, and specifically, the write operation is an essential function for high-speed information processing. In the various memory structures currently in use, data is recorded by activating specific memory cells using voltage, and thereby the storage state is maintained. In resistive memory (resistance random access memory (RRAM), phase-change random access memory (PRAM), magnetoresistive random access memory (MRAM) and so on), a write current is used to write data to the cell, and high current density can affect the durability of memory cells.

### SUMMARY

In general, the present disclosure is directed toward a memory writing method for reducing power consumption in memory writing of a memory device and memory device supporting the same. Specifically, the purpose is to reduce the power consumption of writing to a memory device.

In related art, a method is used to record data in specific cells by adding separate switching devices such as transistors, diodes, and threshold switches within the memory cell. The switching devices may help reduce indiscriminate power consumption by selecting memory cells.

Selector only memory (SOM) has a structure that simultaneously performs memory and cell selection functions using a single substance of the Chalcogenide series. The SOM device may configure memory cells without separate switches such as transistors and diodes by adopting a 2-terminal structure including upper and lower electrodes and a single memory material. The 2-terminal structure includes a cross-point structure where a word line WL in the X direction and a bit line BL in the Y direction intersect, and may achieve high integration compared to dynamic random-access memory (DRAM). Specifically, the cross-point structure is advantageous for high-density data storage because it allows more cells to be placed in the same area while making the memory cells smaller. The SOM devices handle memory cell selection and data recording through a single material, but due to the structural characteristics in which bit lines and word lines are connected simultaneously, excessive power consumption may occur during write operations.

According to some implementations, the present disclosure is directed to a method of writing to a memory, the method including selecting a polarity for writing based on a type of write data, applying a first reference voltage to a first line selected from a word line and a bit line according to an operation of a global decoder pair corresponding to the polarity, in response to the first line reaching the first reference voltage, floating the first line, and applying a second reference voltage to a second line which is different from the first line among the word line and the bit line according to the operation of the global decoder pair.

According to some implementations, the present disclosure is directed to a memory device that includes a plurality of memory cell elements each of which is connected to one of a plurality of bit lines and one of a plurality of word lines, a decoder circuit connected to the plurality of bit lines and the plurality of word lines, and a memory controller configured to perform a data write operation by controlling the decoder circuit, wherein the memory controller is configured to select a polarity for writing based on a type of write data, apply a first reference voltage to a first line selected from a word line and a bit line according to an operation of a global decoder pair corresponding to the polarity, in response to the first line reaching the first reference voltage, float the first line, and apply a second reference voltage to a second line which is different from the first line among the word line and the bit line according to the operation of the global decoder pair.

### BRIEF DESCRIPTION OF THE DRAWINGS

Example implementations will be more clearly understood from the following detailed description, taken in conjunction with the accompanying drawings.

FIG. 1 is a block diagram illustrating an example of a memory device according to some implementations.

FIG. 2A illustrates examples of voltages applied to a selected word line and a selected bit line and an unselected word line and an unselected bit line according to some implementations.

FIG. 2B illustrates an example of a one-way decoder and a memory cell element according to some implementations.

FIG. 2C is a graph illustrating an example of a voltage applied to a word line and a bit line and the current flowing in the one-way decoder and a memory cell element according to some implementations.

FIG. 3A is a graph illustrating examples of current-voltage characteristics of the SOM device according to some implementations.

FIG. 3B is a graph illustrating examples of change in a threshold voltage of the set state according to the write current according to some implementations.

FIG. 4 is a block diagram illustrating examples of a decoder and a memory cell element of a memory device according to some implementations.

FIG. 5 is a flowchart illustrating an example of a method of writing to memory according to some implementations.

FIG. 6 is a circuit diagram illustrating examples of a decoder and a memory cell element of a memory device according to some implementations.

FIG. 7 is a graph illustrating an example of a voltage applied to a word line and a bit line of a memory device and the current flowing therethrough according to some implementations.

FIG. 8A is a circuit diagram illustrating an example of a global decoder applying a positive supply voltage and input signals according to some implementations.

FIG. 8B is a circuit diagram illustrating an example of a global decoder applying a negative supply voltage and input signals according to some implementations.

FIG. 9 is a circuit diagram illustrating examples of a decoder and a memory cell element of a memory device including a reference capacitor according to some implementations.

### DETAILED DESCRIPTION

Hereinafter, example implementations will be explained in detail with reference to the accompanying drawings.

In the present disclosure, when a part is described as “comprising or including” a component, it does not exclude another component but may further include another component unless otherwise stated. Furthermore, terms such as “. . . unit,” “. . . group,” and “. . . module” described in the specification mean a unit that processes at least one function or operation, which may be implemented as hardware, software, or a combination thereof.

Expression “at least one of a, b and c” described throughout the specification may include “a alone,” “b alone,” “c alone,” “a and b,” “a and c,” “b and c” or “all of a, b and c.”

In the present disclosure, a “terminal” may be implemented as, for example, a computer or a portable terminal capable of accessing a server or another terminal through a network. Here, the computer may include, for example, a notebook, a desktop computer, and/or a laptop computer which are equipped with a web browser. The portable terminal may be a wireless communication device ensuring portability and mobility, and include (but is not limited to) any type of handheld wireless communication device, for example, a tablet PC, a smartphone, a communication-based terminal such as international mobile telecommunication (IMT), code division multiple access (CDMA), W-code division multiple access (W-CDMA), long term evolution (LTE), or the like.

In the present disclosure, some elements are exaggerated, omitted or schematically illustrated in the accompanying drawings. In addition, the size of each element does not fully reflect the actual size. In each figure, the same or corresponding elements are assigned the same reference numerals.

It will be understood that each block of a flowchart diagram and a combination of the flowchart diagrams may be performed by computer program instructions. The computer program instructions may be embodied in a processor of a general-purpose computer or a special purpose computer, or may be embodied in a processor of other programmable data processing equipment. Thus, the instructions, executed via a processor of a computer or other programmable data processing equipment, may generate a part for performing functions described in the flowchart blocks. To implement a function in a particular manner, the computer program instructions may also be stored in a computer-usable or computer-readable memory that may direct a computer or other programmable data processing equipment. Thus, the instructions stored in the computer usable or computer readable memory may be produced as an article of manufacture containing an instruction part for performing the functions described in the flowchart blocks. The computer program instructions may be embodied in a computer or other programmable data processing equipment. Thus, a series of operations may be performed in a computer or other programmable data processing equipment to create a computer-executed process, and the computer or other programmable data processing equipment may provide steps for performing the functions described in the flowchart blocks.

Additionally, each block may represent a module, a segment, or a portion of code that includes one or more executable instructions for executing a specified logical function(s). It should also be noted that in some alternative implementations the functions recited in the blocks may occur out of order. For example, two blocks shown one after another may be performed substantially at the same time, or the blocks may sometimes be performed in the reverse order according to a corresponding function.

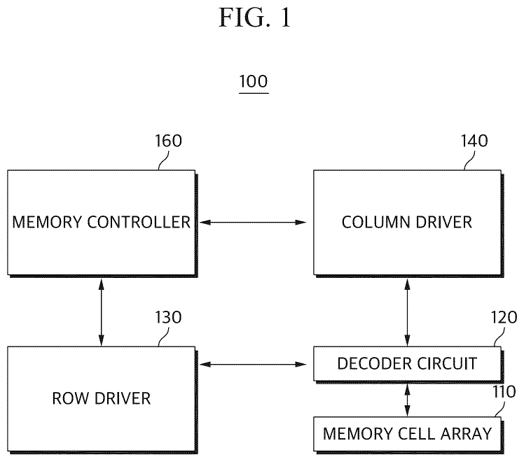

FIG. 1 is a block diagram illustrating an example of a memory device according to some implementations. In FIG. 1, a memory device 100 may include a memory cell array 110, a decoder circuit 120, a row driver 130, a column driver 140, and a memory controller 150. The memory device 100 illustrated in FIG. 1 may include components related to some implementations. Accordingly, other general components may be included in addition to the components illustrated in FIG. 1. The memory device 100 is not limited to that illustrated in FIG. 1 and may be implemented by more diverse components. For example, the memory device 100 may include additional voltage drivers.

The memory cell array 110 may include a plurality of word lines and a plurality of bit lines. For example, the memory cell array 110 may be a cross point memory cell array. The memory cell array 110 may include memory cell elements connected between the word lines and the bit lines. The memory cell element may be an ovonic threshold switch (OTS)-only memory cell element or a selector only memory (SOM) cell device, but the scope of the present disclosure is not limited thereto.

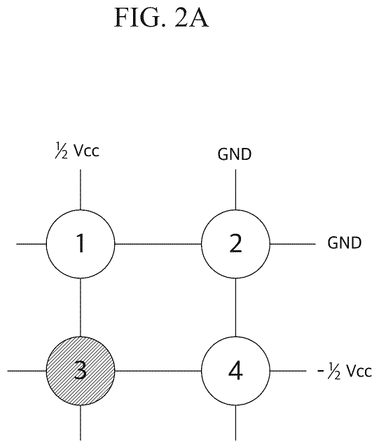

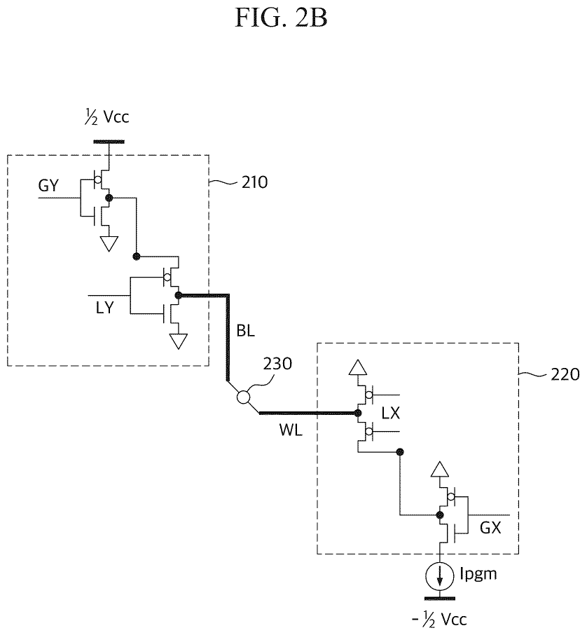

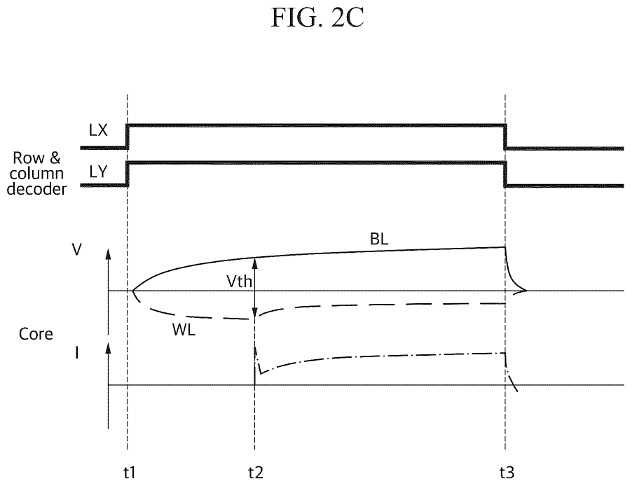

While the SOM cell device remains in a high resistance state, when a certain threshold voltage is applied, the resistance decreases rapidly, and the SOM cell devices may have electrical characteristics of threshold switching, where the resistance value is close to zero. Further, unlike diodes, the SOM cell devices may have the characteristic of being able to switch at both positive and negative voltages. The characteristics of the SOM cell devices are described in detail below with reference to FIG. 2A and FIG. 2B.

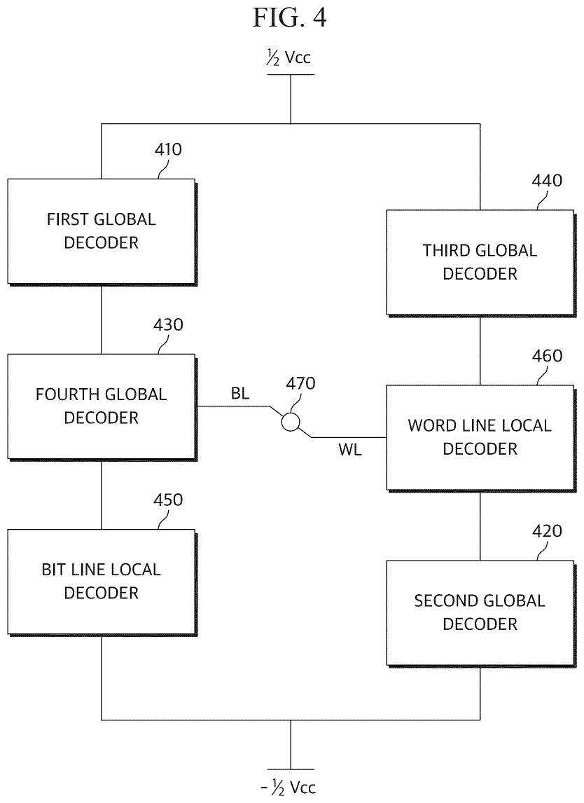

The decoder circuit 120 may apply a voltage to the word line or the bit line of a selected memory cell element included in the memory cell array 110 during a read or write operation for the memory device 100. For example, the decoder circuit 120 may selectively apply the voltage to one word line among the plurality of word lines, and selectively apply the voltage to one bit line among the plurality of bit lines. The configuration and operation method of the decoder circuit 120 are described in detail below with reference to FIGS. 4 to 6.

The row driver 130 may output the voltage to be applied to the plurality of word lines. The decoder circuit 120 may bias the plurality of word lines with the levels (or voltage levels) of the voltages output from the row driver 130. The decoder circuit 120 may float at least one word line among the plurality of word lines at the levels of voltages output from the row driver 130.

The column driver 140 may output the voltage to be applied to the plurality of bit lines. The decoder circuit 120 may bias the plurality of bit lines with the levels (or voltage levels) of the voltages output from the column driver 140. The decoder circuit 120 may float at least one bit line among the plurality of bit lines at the levels of voltages output from the column driver 140.

Further, the column driver 140 may include a voltage driver that controls the voltage of the bit line. The timing signals connected to the voltage driver exist separately from the address signals, and may control the timing of the bit lines. Address signals may control the timing of the word lines, and the address signals may select and activate a specific word line of the memory cell array 110 via the decoder circuit 120 and the row driver 130. The voltage driver signal is input with a delay compared to the address signal, and may control the timing of applying voltage to the bit line. The voltage driver may independently control the timing of the bit lines and the word lines to ensure stable operation of memory cells. The voltage driver may control the voltage to be applied to the bit line through the voltage control circuit based on the input voltage driver signal, and deliver the voltage to the bit line through the output terminal.

A memory controller 160 may perform functions, such as address decoding, data transfer control, timing signal generation and regulation, voltage and current management, and error detection and correction, in the memory device 100. The memory controller 160 may select a specific memory cell element within the memory cell array 110 based on an input address signal, and the memory controller 160 may manage data read and write operations between memory and the processor, and may generate necessary timing signals. Further, the memory controller 160 may control the voltage and current required for the operation of the memory device 100 to ensure stable operation, and may provide error detection and correction capabilities to maintain data integrity.

The memory controller 160 may control the decoder circuit 120, the row driver 130 and the column driver 140. The memory controller 160 may control the biasing or floating of the plurality of word lines and the plurality of bit lines of the decoder circuit 120 by controlling the row driver 130 and the column driver 140. The memory controller 160 may control the biasing signal to separate the timing at which the local driver included in the decoder circuit 120 operates. For example, when the word line WL in the X direction reaches the reference voltage first, the memory controller 160 may float the word lines by applying a biasing signal to the local decoder controlling the word line and stopping the application of the biasing signal to the gate of the local decoder controlling the word line when the voltage of the word line reaches the reference voltage.

Further, the memory controller 160 may determine whether to perform an operation to write data or a read operation to the memory cell array 110 based on the write and read mode signals. Additionally, the memory controller 160 may control the timing of the word lines based on address signals. More specifically, the memory controller 160 may control the operation timing of the local decoder connected to the selected word line by controlling the row driver 130 according to the address signal. Furthermore, according to the write data type, the memory controller 160 may select the polarity and select a global decoder pair of the decoder circuit 120 corresponding to the selected polarity.

The memory controller 160 may select the polarity for writing based on the type of write data, apply a first reference voltage to a first line selected from the word line and the bit line according to the operation of a global decoder pair corresponding to the polarity, float the first line in response to the first line reaching the first reference voltage, and apply a second reference voltage to a second line different from the first line among the word line and the bit line according to the operation of the decoder pair.

FIG. 2A illustrates examples of voltages applied to a selected word line and a selected bit line and an unselected word line and an unselected bit line according to some implementations. In FIG. 2A, the positive supply voltage +½ Vcc may be applied to the bit line corresponding to a third memory cell element, which is the target memory cell element, the negative supply voltage of −½ Vcc may be applied to a word line, and a ground voltage GND may be applied to other bit lines and word lines. In this case, the target memory cell element, which is the third memory cell element, is supplied with Vcc, which is the difference between the voltage applied to the bit line and the voltage applied to the word line, and the resistance of the third memory cell element drops rapidly, allowing data to be written to the memory cell element. Further, a first memory cell element is supplied with ½ Vcc, which is the difference between the voltage applied to the bit line and the voltage applied to the word line, a second memory cell element is charged with 0V, which is the difference between the voltage applied to the bit line and the voltage applied to the word line, and a fourth memory cell element is supplied with ½ Vcc, which is the difference between the voltage applied to the bit line and the voltage applied to the word line, and thus data may not be written to the first, second and fourth memory cell elements, which are not the target memory cell elements.

FIG. 2B illustrates an example of a one-way decoder and a memory cell element according to some implementations. In FIG. 2B, for resistive memory cells 230, such as RRAM cells and PRAM cells, the write operation on a memory cell consumes energy and requires a write operation current greater than the threshold current. Accordingly, a one-way decoder for writing the resistive memory cell 230 may include a first decoder 210 that receives a positive supply voltage (½ Vcc) and provides the positive supply voltage to the bit line, a second decoder 220, which receives a negative supply voltage (−½ Vcc) and provides the negative supply voltage to a word line, and a current source (lgpm) to stably supply the negative supply voltage (−½ Vcc) to the second decoder 220.

The first decoder 210 may include a Y global decoder GY and an inverter-type Y local decoder LY as Y-direction decoders, and the Y global decoder GY may be connected to the positive supply voltage (½ Vcc) and the Y local decoder LY in inverter form, and may supply the positive supply voltage (½ Vcc) to the bit line.

The second decoder 220 may include an X global decoder GX and an X local decoder LX in the form of an inverter as X-direction decoders, and the negative supply voltage (−½ Vcc) may be stably supplied to the word line by the X global decoder GX being connected to the current source (lgpm), and the current source (lgpm) being connected to the negative supply voltage (−½ Vcc).

FIG. 2C is a graph illustrating an example of a voltage applied to a word line and a bit line and the current flowing in the one-way decoder and a memory cell element according to some implementations. In FIGS. 2B and 2C, when the operation signal is applied simultaneously to the gates of the X local decoder LX and the Y local decoder LY at time t₁ by the memory controller 160, the X local decoder LX and the Y local decoder LY are turned on, and voltage V begins to be applied to the bit lines and word lines connected to the memory cell element (Core). When the positive power supply (½ Vcc) and the negative power supply (−½ Vcc) are supplied to the bit line and the word line, respectively, and the absolute value of the voltage level increases, and at time t₂, the difference between the voltage of the bit line and the voltage of the word line reaches the threshold voltage Vₜₕ, the resistance of the memory cell element (Core) decreases rapidly. Accordingly, the energy stored in the word line and the bit line of each cell device (Core) is rapidly released, and the current flowing in the bit line and the word line rapidly increases. In the decoder and memory cell element (Core), current continues to flow by the current source (lgpm) until t3, when the X local decoder LX and the Y local decoder LY are turned off, even after the threshold voltage Vₜₕ is reached, and thus constant power consumption may occur.

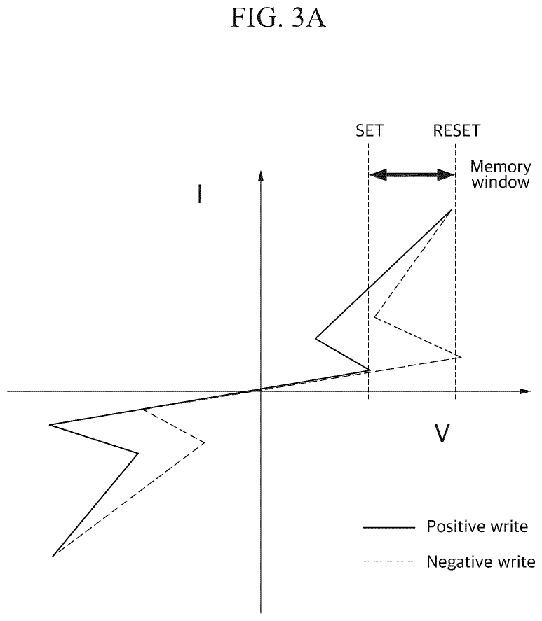

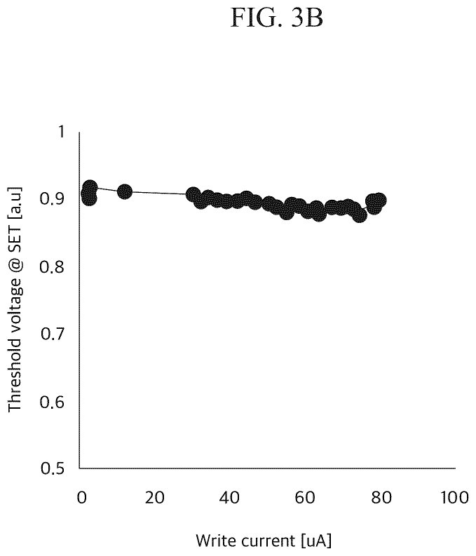

FIG. 3A is a graph illustrating an example of current-voltage characteristics of the SOM device according to some implementations. In FIG. 3A, the SOM device has a characteristic in which a memory window appears because the threshold voltage changes according to the polarity of the write voltage. The graph shows bidirectional switching characteristics, where switching is possible when both positive and negative supply voltages are applied. When a positive voltage is applied to the SOM device (solid line), the SOM device reaches the “SET” state and has the characteristic of lowering the threshold voltage, and when a negative voltage is applied (dotted line), the SOM device has the characteristic of switching to the “RESET” state and increasing the threshold voltage. The characteristics may appear differently according to the write operation at positive voltage (positive write) and the write operation at negative voltage (negative write), and the memory window may be formed.

FIG. 3B is a graph illustrating an example of a change in a threshold voltage of the set state according to the write current according to some implementations. In FIG. 3B, the state of the SOM device may be determined based on the direction of the write voltage, regardless of the amount of the write current. For example, after a positive write voltage is applied, it switches to a low resistance state defined as “D1” or “SET” state, and after a negative write voltage is applied, it switches to a high resistance state defined as “0” or “RESET” state. Further, the SOM device may operate stably even with short write times of less than 30 ns and exhibit low-power write characteristics.

In data writing operations of cross point devices such as SOM devices, the ½ Vcc method may be applied. For example, when the voltage required for a memory cell element is Vcc, the positive supply voltage of ½ Vcc is applied to the selected bit line, and when the negative supply voltage of −½ Vcc is applied to the selected word line, all unselected bit lines and word lines may have ground voltage applied. In this case, the Vcc voltage is applied to the memory cell element at the point where the selected bit line and the selected word line intersect, so that a write operation may be performed on the corresponding memory cell element.

According to some implementations, the memory device may increase the voltage of the memory cell element up to the threshold voltage by supplying power in both directions without a separate current source using the SOM cell device, and may control the timing at which voltage is applied to memory cell elements, the word lines, and the bit lines differently, and power consumption during write operations may be reduced.

Below, a memory device using a SOM cell device by which power consumption during a write operation according to some implementations is reduced is described in detail.

FIG. 4 is a block diagram illustrating examples of a decoder and a memory cell element of a memory device according to some implementations. In FIGS. 1 and 4, the decoder circuit 120 may include a first global decoder 410, a second global decoder 420, a bit line local decoder 430, a third global decoder 440, a fourth global decoder 450, and a word line local decoder 460. The memory controller 160 may select a memory cell element 470 to perform the data write, and select the bit lines and word lines connected to the selected memory cell element 470. The memory controller 160 may control the operation timing of the word line by applying an address signal, and control the operation timing of the bit lines using a voltage driver.

The decoder circuit 120 may not include a current source at the negative supply voltage (−½ Vcc) unlike resistive memory cell elements.

In some implementations, the memory controller 160 may identify the data type to perform data write. The memory controller 160 may select the polarity according to data type, and select a global decoder pair corresponding to the polarity. The global decoder pair may include a first global decoder pair of the first global decoder 410 and the second global decoder 420, and a second global decoder pair of the third global decoder 440 and the fourth global decoder 450.

For example, when the data type is 0, the decoder pair corresponding to the polarity may be the first global decoder pair of the first global decoder 410 and the second global decoder 420. In this case, the voltage may be applied to the bit line BL by the operation of the first global decoder 410 and the bit line local decoder 430, which are supplied with the positive supply voltage (½ Vcc), with respect to the word line WL, the negative supply voltage (−½ Vcc) may be applied to the second global decoder 420, and with the operation of the word line local decoder 460, the voltage may be applied to the word line.

Further, when the data type is 0, the decoder pair corresponding to the polarity may be the second global decoder pair of the third global decoder 440 and the fourth global decoder 450. In this case, the voltage may be applied to the bit line BL due to the operation of the fourth global decoder 450 and the bit line local decoder 430, which are supplied with the negative supply voltage (−½ Vcc), with respect to the word line WL, the positive supply voltage (½ Vcc) may be supplied to the third global decoder 440, and the voltage may be applied to the word line WL from the word line local decoder 460.

In some implementations, the memory controller 160 may control the row driver 130 and the column driver 140 to apply voltage to the bit line BL and the word line WL at different times. For example, when the first global decoder pair is selected, the memory controller 160 may first apply voltage in the word line WL direction. In this case, the memory controller 160 may supply power to the word line WL until it reaches the first voltage level by controlling the row driver 130 to operate the second global decoder 420 and the word line local decoder 460 based on the address signal. When the word line WL reaches the first voltage level, the memory controller 160 may input a floating signal to the word line local decoder 460 to control the word line WL to float without being connected to the ground voltage GND. Further, the memory controller 160 may control the column driver 140 to operate the first global decoder 410 and the bit line local decoder 430 so that the voltage may be applied to the bit line BL. When the voltage difference between the floating word line WL and the charged bit line BL reaches the threshold voltage, since there is no separate current source, the energy stored in the bit line BL and the word line WL may be released instantaneously.

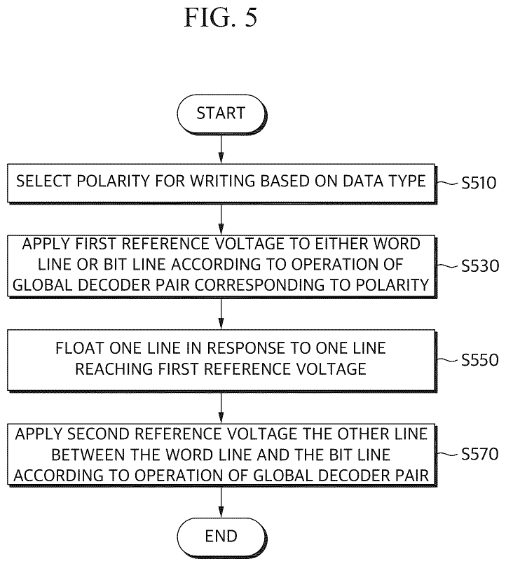

FIG. 5 is a flowchart illustrating an example of a method of writing to memory according to some implementations. In FIG. 5, in operation S510, the memory controller 160 may select polarity for writing based on data type. Here, the data type may indicate the type of data of which a write operation is to be performed on the memory cell element, and may be represented as 0 or 1. A memory cell element according to an example embodiment of the present disclosure is a SOM cell device, and since the memory cell element is a device capable of bidirectional data writing, the polarity of the power supply connected to a bit line and a word line connected to the memory cell element may be switched according to the data type. The polarity according to data type may be defined in advance.

The memory controller 160 may identify whether a data write operation or a data read operation is performed before operation S510. Operation S510 may be performed only if the memory device 100 is identified as performing a data write operation.

In operation S530, the memory controller 160 may apply the first reference voltage to either the word line or the bit line according to the operation of the global decoder pair corresponding to the polarity.

In some implementations, the memory controller 160 may include two global decoder pairs. Each global decoder pair may include a global decoder connected to the positive power supply and a global decoder connected to the negative power supply.

In some implementations, the global decoder pair corresponding to the polarity may be determined in advance. For example, when the data type is 1, the global decoder pair corresponding to the polarity may be the first global decoder pair including a first global decoder connected to a positive supply voltage and supplying a positive supply voltage to the bit line and a second global decoder connected to the negative supply voltage and supplying negative supply voltage to the word line. Further, when the data type is 0, the global decoder pair corresponding to the polarity may be a second global decoder pair including a third global decoder connected to a positive supply voltage and supplying the positive supply voltage to the word line and a fourth global decoder that is connected to the negative supply voltage and supplies the negative supply voltage to the bit line.

The bit line may be connected to the first global decoder and a first local decoder connected to the fourth global decoder, and the word line may be connected to the second global decoder and a second local decoder connected to the third global decoder.

In some implementations, the memory controller 160 may apply voltage from the word line. In operation S550, the memory controller 160 may float one line in response to the one line reaching the first reference voltage.

In some implementations, when the first reference voltage is applied from the word line and the word line reaches the first reference voltage level, the memory controller 160 may float the word line by inputting a floating control signal to the second local decoder. Here, the first reference voltage may be a negative voltage or a positive voltage according to the selected global decoder pair.

In operation S570, the memory controller 160 may apply a second reference voltage to the other line between the word line and the bit line according to the operation of the global decoder pair.

When the first reference voltage is first applied to the word line, when the word line reaches the first reference voltage level, the memory controller 160 may control the first local decoder to apply the second reference voltage to the bit line. Here, the second reference voltage may be related to the moment when the difference between the second reference voltage and the voltage of the floating bit line becomes the threshold voltage at which the memory cell element is fully charged and the resistance drops sharply. In other words, the second reference voltage may be dynamically determined by the difference with the voltage of the bit line.

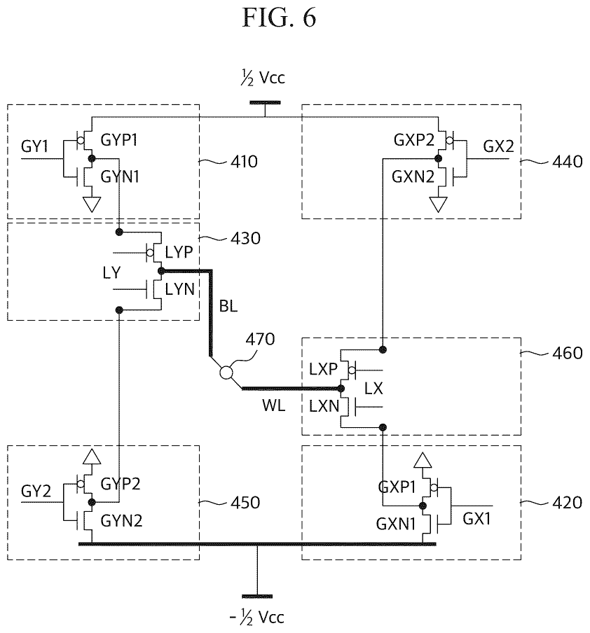

FIG. 6 is a circuit diagram illustrating examples of a decoder and a memory cell element of a memory device according to some implementations. Any content that overlaps with the above descriptions in relation to FIG. 6 will be omitted.

In FIGS. 1 and 6, the decoder circuit 120 may include the first global decoder GY1 410, the second global decoder GX1 420, the bit line local decoder LY 430, the third global decoder GX2 440, the fourth global decoder GY2 450 and the word line local decoder LX 460.

In some implementations, each decoder may contain two transistors of different types, and each global decoder may have the gates of two transistors tied to a common node.

The bit line local decoder LY 430 may include a first transistor LYP and a second transistor LYN. The gate of the first transistor LYP receives the first operation signal based on the polarity and whether it is floating. One end of the first transistor LYP may be connected to the first global decoder GY1 410, and the other end of the first transistor LYP may be connected to one end of the second transistor LYN and the bit line BL. Further, the gate of the second transistor LYN may be connected to the first transistor LYP through a common node in order for the first operation signal to be input. One end of the second transistor LYN may be connected to the fourth global decoder GY2 450, and the other end of the second transistor LYN may be connected to the other end of the first transistor LYP and the bit line BL.

Here, the first input signal may be determined by the global decoder pair corresponding to the polarity selected by the memory device 100, and when it is determined to first apply voltage to the bit line BL and float the bit line BL that has reached the first reference voltage level, the floating signal may be input.

The word line local decoder LX 460 may include a third transistor LXP and a fourth transistor LXN. The gate of the third transistor LXP may receive a second operation signal based on the polarity and whether it is floating. One end of the third transistor LXP may be connected to the second global decoder GX1 420, and the other end of the third transistor LXP may be connected to one end of the fourth transistor LXN and the word line WL. Further, the gate of the fourth transistor LXN may receive the second operation signal. One end of the fourth transistor LXN is connected to the third global decoder GX2 440, and the other end of the fourth transistor LXN may be connected to the other end of the third transistor LXP and the word line WL.

Here, the second input signal may be determined according to the global decoder pair corresponding to the polarity selected by the memory device 100. When it is determined to first apply the first reference voltage to the word line WL and float the word line WL that has reached the first reference voltage level, a floating signal may be input.

In some implementations, the first transistor LYP and the third transistor LXP may be P-channel metal-oxide-semiconductor (PMOS) type transistors, and the second transistor LYN and the fourth transistor LXN may be N-channel metal-oxide-semiconductor (NMOS) type transistors.

The first global decoder GY1 410 may include a fifth transistor GYP1 and a sixth transistor GYN1. A first control signal according to the polarity may be input to the gate of the fifth transistor GYP1. The positive supply voltage is applied to one end of the fifth transistor GYP1, and the other end of the fifth transistor GYP1 may be connected to one end of the sixth transistor GYN1 and the first local decoder LY 430. Further, the first control signal is input to the gate of the sixth transistor GYN1, and the other end of the sixth transistor GYN1 may be connected to the ground voltage.

The second global decoder GX1 420 may include a seventh transistor GXN1 and an eighth transistor GXP1. A second control signal according to the polarity may be input to the gate of the seventh transistor GXN1. The negative supply voltage is applied to one end of the seventh transistor GXN1, and the other end of the seventh transistor GXN1 may be connected to one end of the eighth transistor GXP1 and the second local decoder. Further, the second control signal is input to the gate of the eighth transistor GXP1, and the other end of the eighth transistor GXP1 may be connected to the ground voltage.

The third global decoder GX2 440 may include a ninth transistor GXP2 and a tenth transistor GXN2. A third control signal according to the polarity may be input to the gate of the ninth transistor GXP2. The positive supply voltage is applied to one end of the ninth transistor GXP2, and the other end of the ninth transistor GXP2 may be connected to one end of the tenth transistor GXN2 and the second local decoder. Further, the third control signal is input to the gate of the tenth transistor GXN2, and the other end of the tenth transistor GXN2 may be connected to the ground voltage.

The fourth global decoder GY2 450 may include an eleventh transistor GYN2 and a twelfth transistor GYP2. A fourth control signal according to the polarity may be input to the gate of the eleventh transistor GYN2. The negative supply voltage is applied to one end of the eleventh transistor GYN2, and the other end of the eleventh transistor GYN2 may be connected to one end of the twelfth transistor GYP2 and the first local decoder. Further, the fourth control signal is input to the gate of the twelfth transistor GYP2, and the other end of the twelfth transistor GYP2 may be connected to the ground voltage.

In some implementations, the fifth transistor GYP1, the eighth transistor GXP1, the ninth transistor GXP2 and the twelfth transistor GYP2 may be PMOS type transistors. Further, the sixth transistor GYN1, the seventh transistor GXN1, the tenth transistor GXN2, and the eleventh transistor GYN2 may be NMOS type transistors.

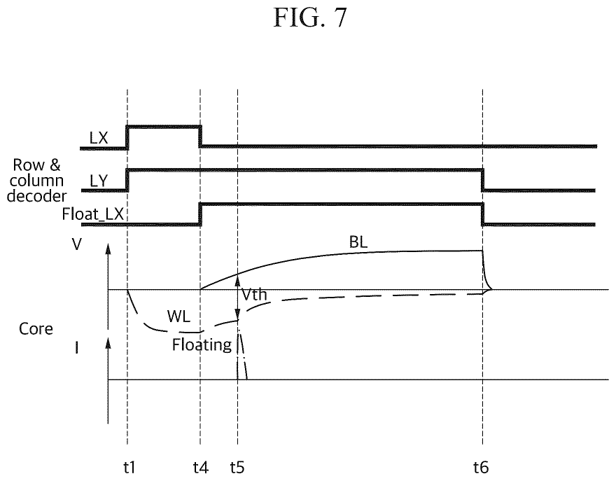

FIG. 7 is a graph illustrating an example of a voltage applied to a word line and a bit line of a memory device and the current flowing therethrough according to some implementations. However, the present disclosure may also include a case where voltage is applied to the bit line first and then to the word line.

In FIG. 7, at time t₁, a negative voltage is first applied to the word line WL, and at time t₄, when the voltage of the word line WL reaches the first reference voltage, the LX signal input of the low decoder is stopped, and the word line WL voltage may be floated with an input of the floating signal Float_LX. The floating word line is not connected to the ground potential, and the absolute value of the voltage gradually decreases.

At time t₄ or later when the word line WL is floating, a LY signal may be input to the column decoder, which may apply a positive voltage to the bit line BL. As the voltage of the bit line BL gradually increases, the resistance of the memory cell element (Core) decreases rapidly at time t₅ when the difference between the voltage of the bit line BL and the voltage of the floating word line reaches the threshold voltage Vₜₕ. The charge stored in the capacitors of the word line WL and the bit line BL may be discharged momentarily, causing a sudden current flow. After a momentary discharge at time t₅, there is no separate current source until time t₆ when the write operation ends, and thus the current flowing through the word line WL and the bit line BL also becomes 0, so no additional power consumption may occur.

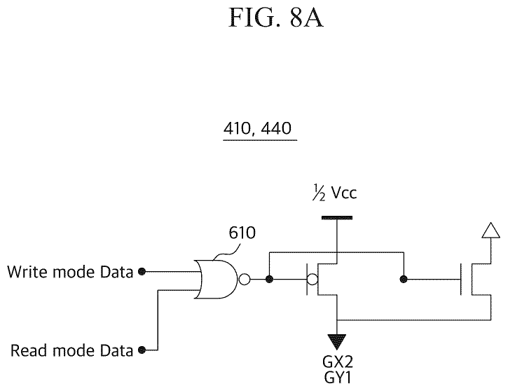

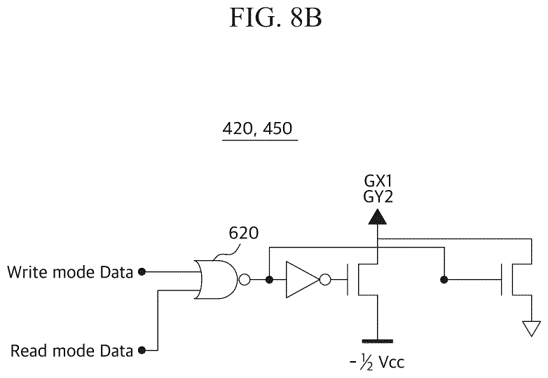

FIG. 8A is a circuit diagram illustrating an example of a global decoder applying a positive supply voltage and input signals according to some implementations. In FIGS. 6 and 8A, an output signal of a NOR gate 610 may be input to each common gate of the first global decoder GY1 410 and the third global decoder GX2 440. The NOR gate 610 may receive a write or read mode selecting signal (a read mode) and a write data type signal (a write mode), and pass the signals through a NOR logic operation and output the signals to each common gate of the first global decoder GY1 410 and the third global decoder GX2 440.

For example, when it is in the write mode and the write data type signal is 0, in the NOR gate, 0 (low) is input as the read mode selecting signal (the read mode), and 0 (low) is input as the write data type signal (the write mode). Thus, a 1 (high) signal may be input to each common gate of the first global decoder GY1 410 and the third global decoder GX2 440.

FIG. 8B is a circuit diagram illustrating an example of a global decoder applying a negative supply voltage and input signals according to some implementations. In FIGS. 6 and 8B, the output signal of a NOR gate 630 may be input to each common gate of the second global decoder GX1 420 and the fourth global decoder GY2 450. Further, FIG. 8B illustrates the PMOS type eighth transistor GXP1 and the PMOS type twelfth transistor GYP2 as a combination of the NOR gate and NMOS type transistors.

The NOR gate 630 may receive a write or read mode selecting signal (the read mode) and a write data type signal (write mode), and perform a NOR logic operation to deliver the output signals to each common gate of the second global decoder GX1 420 and the fourth global decoder GY2 450.

For example, when it is in the write mode and the write data type signal is 0, in the NOR gate, 0 (low) is input as the write or read mode selecting signal (the read mode), and 0 (low) is input as the write data type signal (write mode). Thus, the 1 (high) signal may be input to each common gate of the second global decoder GX1 420 and the fourth global decoder GY2 450.

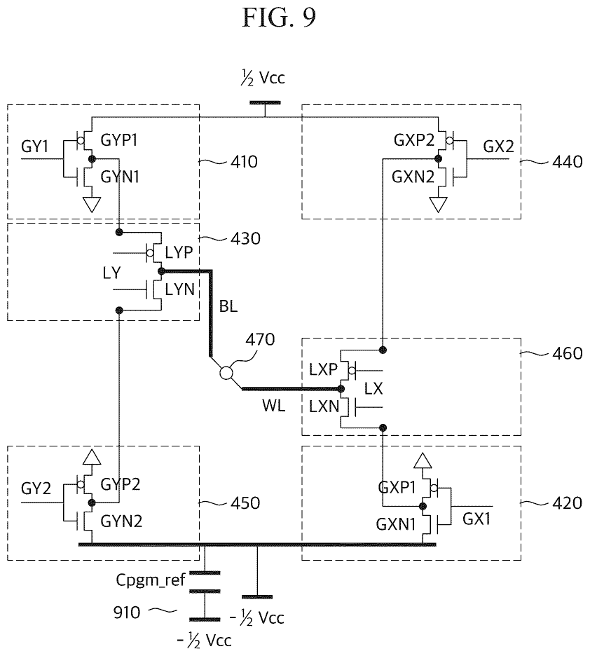

FIG. 9 is a circuit diagram illustrating examples of a decoder and a memory cell element of a memory device including a reference capacitor according to some implementations. In FIG. 9, any content that overlaps with the above description with reference to FIG. 6 will be omitted.

In FIGS. 2 and 9, the decoder circuit 120 may additionally connect the reference capacitor Cpgm_ref between the negative supply voltage (−½ Vcc) and a sensing data line SDL to which the second global decoder GX1 420 and the fourth global decoder GY2 450 are connected.

The dispersion of programming states may be minimized by the reference capacitor Cpgm_ref being connected between the sensing data line SDL and the negative supply voltage (−½ Vcc), causing a certain amount of charge to be lost when the snap-back phenomenon occurs.

Here, the snap-back phenomenon may indicate a phenomenon in which a large amount of current suddenly flows as the resistance of the semiconductor device rapidly decreases when a certain voltage or higher is applied to the device.

The memory device 100 may include a processor, a memory for storing and executing program data, permanent storage, such as disk drives, communication ports to communicate with external devices and user interface devices, such as touch panels, keys and buttons. Methods implemented as software modules or algorithms are computer readable codes or program instructions executable on the processor, and may be stored on a computer-readable recording medium. Here, the computer-readable recording medium includes a magnetic storage medium (for example, a read-only memory (ROM), a random-access memory (RAM), a floppy disk and a hard disk) and an optically readable medium (for example, a CD-ROM, a digital versatile disc (DVD)). The computer-readable recording medium may be distributed among network-connected computer systems, so that a computer-readable code may be stored and executed in a distributed manner. The medium may be readable by a computer, stored in a memory, and executed on a processor.

In the present disclosure, some implementations may be represented by functional block elements and various processing steps. The functional blocks may be implemented in any number of hardware and/or software configurations that perform specific functions. For example, some implementations may adopt integrated circuit configurations, such as memory, processing, logic and/or look-up table, that may execute various functions by the control of one or more microprocessors or other control devices. Similar to that elements may be implemented as software programming or software elements, the example embodiments may be implemented in a programming or scripting language such as C, C++, Java, assembler, etc., including various algorithms implemented as a combination of data structures, processes, routines, or other programming constructs. Functional aspects may be implemented in an algorithm running on one or more processors. Further, the example embodiments may adopt the existing art for electronic environment setting, signal processing, and/or data processing. Terms such as “mechanism,” “element,” “means” and “configuration” may be used broadly and are not limited to mechanical and physical elements. The terms may include the meaning of a series of routines of software in association with a processor or the like.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A method of writing to a memory, the method comprising:
selecting a polarity for writing based on a type of write data;
applying a first reference voltage to a first line according to an operation of a global decoder pair corresponding to the polarity, the first line being a word line or a bit line;
in response to the first line reaching the first reference voltage, placing the first line in a floating state; and
applying a second reference voltage to a second line according to the operation of the global decoder pair, the second line being the word line or the bit line and being different from the first line.

2. The method of claim 1, wherein the global decoder pair comprises:
a first global decoder pair comprising a first global decoder that is configured to select a positive supply voltage to be applied to the bit line and a second global decoder that is configured to select a negative supply voltage to be applied to the word line; and
a second global decoder pair comprising a third global decoder that is configured to select the positive supply voltage to be applied to the word line and a fourth global decoder that is configured to select the negative supply voltage to be applied to the bit line.

3. The method of claim 2,
wherein, based on a type of the write data being a logic 1, the global decoder pair corresponding to the polarity is the first global decoder pair, and
wherein, based on a type of the write data being a logic 0, the global decoder pair corresponding to the polarity is the second global decoder pair.

4. The method of claim 2,
wherein the bit line is connected to the first global decoder and a first local decoder connected to the fourth global decoder, and
wherein the word line is connected to the second global decoder and a second local decoder connected to the third global decoder.

5. The method of claim 4,
wherein the first local decoder is configured to receive a first operation signal generated based on the polarity and a floating status of the first line, and
wherein the first local decoder is configured to select the positive supply voltage to be applied to the bit line according to an operation of the first global decoder and the first operation signal, and to select the negative supply voltage to be applied to the bit line according to an operation of the fourth global decoder and the first operation signal,
wherein the second local decoder is configured to receive a second operation signal generated based on the polarity and the floating status of the first line, and
wherein the second local decoder is configured to select the negative supply voltage to be applied to the word line according to an operation of the second global decoder and the second operation signal, and to select the positive supply voltage to be applied to the bit line according to an operation of the third global decoder and the second operation signal.

6. The method of claim 4,
wherein the first global decoder comprises a first transistor and a second transistor that have a first common gate configured to receive a first control signal corresponding to the polarity, the first transistor and the second transistor being connected to each other via a first node connected to the first local decoder,
wherein the second global decoder comprises a third transistor and a fourth transistor that have a second common gate configured to receive a second control signal corresponding to the polarity, the third transistor and the fourth transistor being connected to each other via a second node connected to the second local decoder,
wherein the third global decoder comprises a fifth transistor and a sixth transistor that have a third common gate configured to receive a third control signal corresponding to the polarity, the fifth transistor and the sixth transistor being connected to each other via a third node connected to the first local decoder, and
wherein the fourth global decoder comprises a seventh transistor and an eighth transistor that have a fourth common gate configured to receive a fourth control signal corresponding to the polarity, the seventh transistor and the eighth transistor being connected to each other via a fourth node connected to the second local decoder.

7. The method of claim 6,
wherein the first transistor, the fourth transistor, the fifth transistor, and the eighth transistor are P-channel metal-oxide-semiconductor (PMOS) type transistors, and
wherein the second transistor, the third transistor, the sixth transistor, and the seventh transistor are N-channel metal-oxide-semiconductor (NMOS) type transistors.

8. The method of claim 6, wherein the first control signal and the third control signal is an output signal of a NOR gate configured to receive a signal according to a type of the write data and a signal according to a write mode or a read mode.

9. The method of claim 6, wherein the second control signal and the fourth control signal is an output signal of a NOR gate configured to receive a signal according to a type of the write data and a signal according to a write mode or a read mode.

10. The method of claim 2, comprising a reference capacitor connected between a node connected to the second global decoder and the fourth global decoder and a node of the negative supply voltage.

11. The method of claim 1, wherein the memory comprises a selector only memory (SOM) cell device.

12. A memory device comprising:
a plurality of memory cell elements, each being connected to one of a plurality of bit lines and one of a plurality of word lines;
a decoder circuit connected to the plurality of bit lines and the plurality of word lines; and
a memory controller configured to perform a data write operation by controlling the decoder circuit,
wherein the memory controller is configured to:
select a polarity for writing based on a type of write data;
apply a first reference voltage to a first line according to an operation of a global decoder pair corresponding to the polarity, the first line being a word line among the plurality of word lines or a bit line among the plurality of bit lines;
in response to the first line reaching the first reference voltage, placing the first line in a floating state; and
apply a second reference voltage to a second line according to the operation of the global decoder pair, the second line being the word line or the bit line and being different from the first line.

13. The memory device of claim 12, wherein the global decoder pair comprises:
a first global decoder pair comprising a first global decoder that is configured to select a positive supply voltage to be applied to the bit line and a second global decoder that is configured to select a negative supply voltage to be applied to the word line; and
a second global decoder pair comprising a third global decoder that is configured to select the positive supply voltage to be applied to the word line and a fourth global decoder that is configured to select the negative supply voltage to be applied to the bit line.

14. The memory device of claim 13,
wherein, based on a type of the write data being a logic 1, the global decoder pair corresponding to the polarity is the first global decoder pair, and
wherein, based on a type of the write data being a logic 0, the global decoder pair corresponding to the polarity is the second global decoder pair.

15. The memory device of claim 13,
wherein the bit line is connected to the first global decoder and a first local decoder connected to the fourth global decoder, and
wherein the word line is connected to the second global decoder and a second local decoder connected to the third global decoder.

16. The memory device of claim 15,
wherein the first local decoder is configured to receive a first operation signal generated based on the polarity and a floating status of the first line,
wherein the first local decoder is configured to select the positive supply voltage to be applied to the bit line according to an operation of the first global decode and the first operation signal, and to select the negative supply voltage to be applied to the bit line according to an operation of the fourth global decoder and the first operation signal,
wherein the second local decoder is configured to receive a second operation signal generated based on the polarity and the floating statue of the first line, and
wherein the second local decoder is configured to select the negative supply voltage to be applied to the word line according to an operation of the second global decoder and the second operation signal, and to select the positive supply voltage to be applied to the bit line according to an operation of the third global decoder and the second operation signal.

17. The memory device of claim 15,
wherein the first global decoder comprises a first transistor and a second transistor that have a first common gate configured to receive a first control signal corresponding to the polarity, the first transistor and the second transistor being connected to each other via a first node connected to the first local decoder,
wherein the second global decoder comprises a third transistor and a fourth transistor that have a second common gate configured to receive a second control signal corresponding to the polarity, the third transistor and the fourth transistor being connected to each other via a second node connected to the second local decoder,
wherein the third global decoder comprises a fifth transistor and a sixth transistor that have a third common gate configured to receive a third control signal corresponding to the polarity, the fifth transistor and sixth transistor being connected to each other via a third node connected to the first local decoder, and
wherein the fourth global decoder comprises a seventh transistor and an eighth transistor that have a fourth common gate configured to receive a fourth control signal corresponding to the polarity, the seventh transistor and the eighth transistor being connected to each other via a fourth node connected to the second local decoder.

18. The memory device of claim 17, wherein the first control signal and the third control signal is an output signal of a NOR gate configured to receive a signal according to a type of the write data and a signal according to a write mode or a read mode.

19. The memory device of claim 13, comprising a reference capacitor connected between a node connected to the second global decoder and the fourth global decoder and a node of the negative supply voltage.

20. The memory device of claim 12, wherein the memory cell elements comprise selector only memory (SOM) cell devices.
